(19) United States
(12) Patent Application Publication
(10) Pub. No.: US 2024/0363562 A1
(43) Pub. Date: Oct. 31, 2024

(54) Packaging Structure for Large-Size Chips Adapted to Small-Size Packages and Processing Method Thereof

(71) Applicant: SHENZHEN SIPTORY TECHNOLOGY CO., LTD, Shenzhen (CN)

(72) Inventor: Dongdong Shao, Shenzhen (CN)

(21) Appl. No.: 18/764,147

(22) Filed: Jul. 3, 2024

Related U.S. Application Data
(63) Continuation of application No. PCT/CN2023/072053, filed on Jan. 13, 2023.

(30) Foreign Application Priority Data
Jan. 27, 2022 (CN) 202210099768.3

(51) Int. Cl. H01L 23/00; H01L 23/31

(52) U.S. Cl. CPC H01L 24/05; H01L 23/3185; H01L 24/03; H01L 2224/03462; H01L 2224/03632; H01L 2224/0384; H01L 2224/05567; H01L 2924/38

(57) ABSTRACT

The present invention discloses a packaging structure for large-size chips adapted to small-size packages and a processing method thereof, wherein the first solder pad cavity and the second solder pad cavity are intersected and misaligned; the channel is located on one side of the two solder pad cavities, with the inner wall of the channel being a metallized hole wall; by providing a channel with a metallized hole wall on the proximal side of the packaging structure, more space is provided for chips, which meets the processing needs for large-size chips adapted to small-size packages.

### CROSS REFERENCE TO RELATED APPLICATIONS

The present application is a Continuation Application of PCT Application No. PCT/CN2023/072053 filed on Jan. 13, 2023, which claims the benefit of Chinese Patent Application No. 202210099768.3 filed on Jan. 27, 2022. All the above are hereby incorporated by reference in their entirety.

### TECHNICAL FIELD

The present application relates to the technical field of chip packaging, in particular a packaging structure for large-size chips adapted to small-size packages and a processing method thereof.

### BACKGROUND ART

With the development of the semiconductor industry, on one hand, the performance, power and other parameters of chips have been greatly enhanced with the increase in the size of chips; on the other hand, the miniaturization of devices requires the package size of products to be increasingly smaller. There is a certain conflict between the two: how to package a chip with a larger size within a smaller size of package to meet higher performance demands.

### Technical Problems

Currently, in common packaging structures of products, as shown in FIG. 1, a first solder pad initial cavity 11, a second solder pad initial cavity 21, and a chip cavity 41 are set within the package, as well as a first solder pad, a second solder pad, and a chip correspondingly set therein. The chip is connected to the second solder pad through electrical connection wire 42. The proportion of the chip itself in the package is usually very small, generally accounting for less than 30%. As shown in FIG. 2, there are also packaging structures for larger chips realized through complex multi-layer wiring. At least two layers of wiring also require complex via connections. However, the design of multi-layer wiring plus inter-layer vias brings great difficulty to the packaging process, complicates the process flow, reduces work efficiency, and increases the cost of product production.

### Technical Solutions

In light of the above problems, the present application provides a packaging structure for large-size chips adapted to small-size packages, allowing for the packaging of larger-size chips within smaller packages without complex via connections.

In a first aspect, the present invention provides a packaging structure for large-size chips adapted to small-size packages, including a frame, a first solder pad cavity and a second solder pad cavity located in the frame, and a chip cavity located above the first solder pad cavity, a channel opened on the proximal side of the frame. The first solder pad cavity partly extends above part of the second solder pad cavity, and is spaced apart from the second solder pad cavity. The first solder pad cavity and the second solder pad cavity are intersected and misaligned. The channel is located on the same left or right side of the two solder pad cavities (on one side of the two solder pad cavities), with the inner wall of the channel being a metallized hole wall.

Preferably, the first solder pad cavity, the second solder pad cavity, and the chip cavity are respectively adapted to the first solder pad, the second solder pad, and the chip.

Optionally, the first solder pad cavity comprises a first pad bottom cavity and a first pad body cavity located above the first pad bottom cavity, wherein the first pad body cavity extends above the second solder pad cavity.

Optionally, the cross-sectional area of the first pad body cavity is greater than the cross-sectional area of the first pad bottom cavity.

Optionally, the second solder pad cavity comprises a second pad bottom cavity and a second pad body cavity located above the second pad bottom cavity, wherein the second pad body cavity is connected to the channel.

Optionally, the first pad body cavity extends above the pad bottom cavity.

Optionally, the first pad body cavity and the second pad body cavity are laterally spaced apart from each other.

Optionally, the first pad body cavity and the second pad bottom cavity are longitudinally spaced apart from each other.

Optionally, an electrical connection wire is provided between the chip cavity and the channel.

In a second aspect, the present invention provides a processing method for the above packaging structure for large-size chips adapted to small-size packages, characterized in comprising the following steps:
Initial injection molding a conventional frame until injection molding materials fill the original plastic packaging cavity;
Thickening the first solder pad initial cavity by electroplating to form the first pad bottom cavity;
Secondary plastic packaging filling to be flush with the top surface of the first pad bottom cavity;
Processing by electroplating to form the first pad body cavity of the first solder pad cavity;
Placing the first solder pad and the second solder pad respectively in the first solder pad cavity and the second solder pad cavity, and then soldering and mounting the chip on the top surface of the first solder pad;
Drilling a hole on the same left or right side of the two solder pads (on one side of the two solder pads) and on the proximal edge of the frame to form a channel, and then metallizing the inner wall of the channel to form a metallized hole wall;
Electrically connecting the chip to the metalized hole wall, and electrically connecting the second solder pad to the metalized hole wall;
Further filling the frame by injection molding to form a complete packaging structure.

Optionally, after the step of processing by electroplating to form the first pad body cavity of the first solder pad cavity, the following step is further comprised:

Forming the second pad body cavity of the second solder pad cavity by laser ablation combined with electroplating processing based on the second solder pad initial cavity.

Optionally, in the step of drilling a hole on the same left or right side of the two solder pads and on the proximal edge of the frame to form a channel, and metallizing the inner wall of the channel to form a metallized hole wall, the inner wall of the channel is subjected to electroless copper plating to form the metallized hole wall.

Optionally, in the step of drilling a hole on the same left or right side of the two solder pads and on the proximal edge of the frame to form a channel, and metallizing the inner wall of the channel to form a metallized hole wall, the inner wall of the channel is subjected to sputtering to form the metallized hole wall.

Optionally, in the step of drilling a hole on the same left or right side of the two solder pads and on the proximal edge of the frame to form a channel, and metallizing the inner wall of the channel to form a metallized hole wall, the inner wall of the channel is subjected to electroplating to form the metallized hole wall.

Optionally, in the step of drilling a hole on the same left or right side of the two solder pads (on one side of the two solder pads) and on the proximal edge of the frame to form a channel, and metallizing the inner wall of the channel to form a metallized hole wall, the channel is shaped by processing a through-hole using a high-power ultraviolet laser cutting process with argon gas as the auxiliary gas.

By providing a channel with a metallized hole wall on the proximal side of the packaging structure, the packaging structure for large-size chips adapted to small-size packages provided in the present application effectively saves internal space within the packaging structure, provides more space for the chip inside the packaging structure, effectively increases the proportion of the chip within the packaging structure to 60%-70% compared to traditional packaging structures, and meets the processing needs for large-size chips adapted to small-size packages.

### DESCRIPTION OF DRAWINGS

A detailed description of the embodiments of the present application is provided below by combining with the drawings, which will make the technical solutions of the present application and other advantageous effects obvious.

FIG. 1 is a schematic diagram of the existing chip package;

FIG. 2 is another schematic diagram of the existing chip package;

FIG. 3 is a schematic diagram of the packaging structure for large-size chips adapted to small-size packages provided in the examples of the present application;

FIG. 4 is a diagram of steps for preparing a conventional frame of the packaging structure for large-size chips adapted to small-size packages provided in the examples of the present application;

FIG. 5 is a diagram of the processing step for the initial injection molding of the conventional frame of the packaging structure for large-size chips adapted to small-size packages provided in the examples of the present application;

FIG. 6 is a diagram of the processing step of thickening the first solder pad initial cavity by electroplating for the packaging structure for large-size chips adapted to small-size packages provided in the examples of the present application;

FIG. 7 is a diagram of the processing step of the secondary plastic packaging filling for the packaging structure for large-size chips adapted to small-size packages provided in the examples of the present application;

FIG. 8 is a diagram of the processing step of forming a recess through laser ablation for the packaging structure for large-size chips adapted to small-size packages provided in the examples of the present application;

FIG. 9 is a diagram of the processing step of forming a first solder pad body cavity by electroplating processing for the packaging structure for large-size chips adapted to small-size packages provided in the examples of the present application;

FIG. 10 is a diagram of the processing step of forming a first solder pad body cavity by electroplating processing excluding filling of plastic packaging materials for the packaging structure for large-size chips adapted to small-size packages provided in the examples of the present application;

FIG. 11 is another diagram of the processing step of forming a first solder pad body cavity by electroplating processing for the packaging structure for large-size chips adapted to small-size packages provided in the examples of the present application;

FIG. 12 is another diagram of the processing step of forming a first solder pad body cavity by electroplating processing excluding filling of plastic packaging materials for the packaging structure for large-size chips adapted to small-size packages provided in the examples of the present application;

FIG. 13 is a diagram of the processing step of placing the first solder pad and the second solder pad and mounting the chip for the packaging structure for large-size chips adapted to small-size packages provided in the examples of the present application;

FIG. 14 is another diagram of the processing step of placing the first solder pad and the second solder pad and mounting the chip for the packaging structure for large-size chips adapted to small-size packages provided in the examples of the present application;

FIG. 15 is a diagram of the processing step before the PCB board arrangement and separation for the packaging structure for large-size chips adapted to small-size packages provided in the examples of the present application;

FIG. 16 is a diagram of the processing step before processing the channel on the PCB board for the packaging structure for large-size chips adapted to small-size packages provided in the examples of the present application;

FIG. 17 is a diagram of the processing step after processing the channel on the PCB board for the packaging structure for large-size chips adapted to small-size packages provided in the examples of the present application;

FIG. 18 is a diagram of the processing step before separation after processing the channel on the PCB board for the packaging structure for large-size chips adapted to small-size packages provided in the examples of the present application;

FIG. 19 is a diagram of the processing step after separation after processing the channel on the PCB board for the packaging structure for large-size chips adapted to small-size packages provided in the examples of the present application;

FIG. 20 is another diagram of the processing step after separation after processing the channel on the PCB board for the packaging structure for large-size chips adapted to small-size packages provided in the examples of the present application.

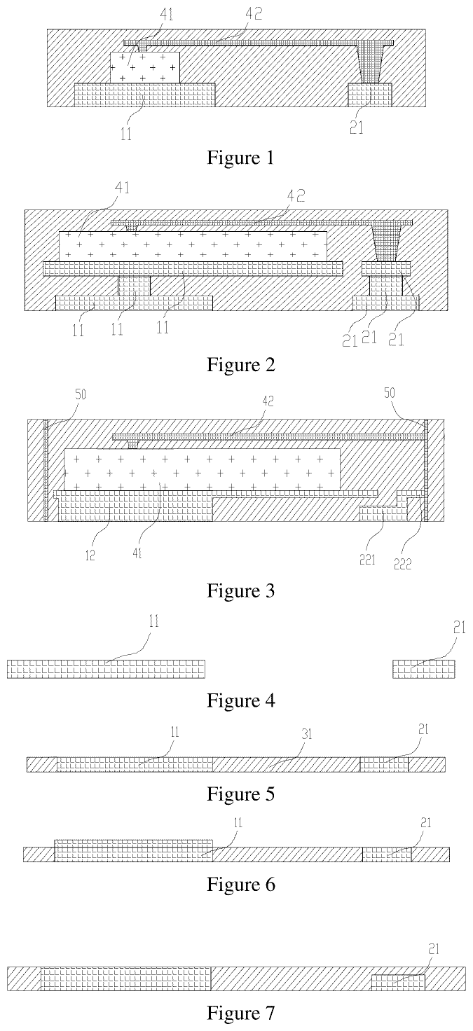

Wherein the components in the drawings are labeled as:
11 a first solder pad initial cavity; 12 a first solder pad cavity; 121 a first pad bottom cavity; 122 a first pad body cavity; 21 a second solder pad initial cavity; 22 a second solder pad cavity; 221 a second pad bottom cavity; 222 a second pad body cavity; 24 a recess; 31 a primary plastic packaging material; 32 a filling plastic packaging material; 41 a chip cavity; 42 an electrical connection wire; 50 a channel; 51 a metallized pore wall; 61 a cutting line; 100 a packaging structure.

### BEST MODES FOR CARRYING OUT THE INVENTION

The present invention provides a processing method for the above packaging structure for large-size chips adapted to small-size packages, comprising the following steps:
S100, as shown in FIG. 4, preparing a conventional frame, initially injection molding the conventional frame until injection molding materials fill the original plastic packaging cavity, wherein the primary plastic packaging material 31 formed by filling is shown in FIG. 5;
S200, as shown in FIG. 6, thickening the first solder pad initial cavity 11 by electroplating to form the first pad bottom cavity 121;
S300, as shown in FIG. 7, secondary plastic packaging filling to be flush with the top surface of the first pad bottom cavity 121;
S400, as shown in FIGS. 9-12, processing by electroplating to form the first pad body cavity 122 of the first solder pad cavity 12;
S500, as shown in FIGS. 13-14, placing the first solder pad and the second solder pad respectively in the first solder pad cavity 12 and the second solder pad cavity 22, and soldering and mounting the chip on the top surface of the first solder pad, wherein filling plastic packaging material 32 can be seen;
S600, drilling a hole on the same left or right side of the two solder pads (on one side of the two solder pads) and on the proximal edge of the frame to form a channel 50, and metallizing the inner wall of the channel 50 to form a metallized hole wall 51;
S700, electrically connecting the chip to the metalized hole wall 51, and electrically connecting the second solder pad to the metalized hole wall 51;
S800, further filling the frame by injection molding to form a complete packaging structure 100.

In an example, as shown in FIG. 14, based on the different sizes of chips within the packaging structure 100, when the size of the chip to be packaged is relatively small, the second soler pad cavity 22 can be implemented as a setting with unflush top and bottom to provide an electrical connection end of the channel 50 not at the end face of the packaging structure 100. After the step of processing by electroplating to form the first pad body cavity 122 of the first solder pad cavity 12, the following step is further comprised:

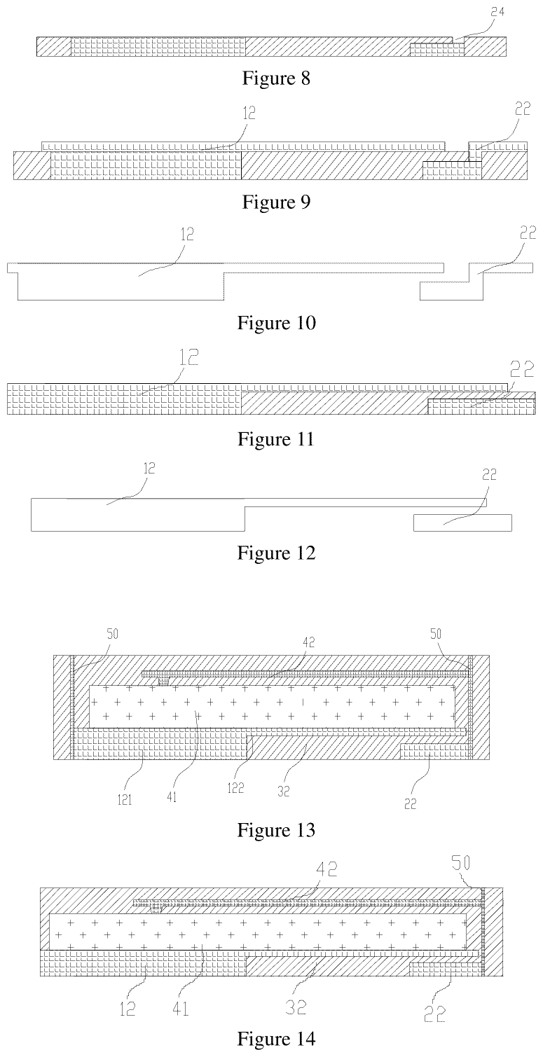

As shown in FIG. 8, forming a recess 24 by laser ablation of the second pad body cavity 222 based on the second solder pad initial cavity 21, which combines with electroplating processing to form the second pad body cavity 222 of the second solder pad cavity 22 as shown in FIG. 9.

In an example, in the step of drilling a hole on the same left or right side of the two solder pads (on one side of the two solder pads) and on the proximal edge of the frame to form a channel 50, and metallizing the inner wall of the channel 50 to form a metallized hole wall 51, the inner wall of the channel 50 is subjected to electroless copper plating, sputtering or electroplating to form the metallized hole wall 51.

### Embodiments of the Present Invention

A clear and complete description of the technical solutions in the examples of the present application is provided below by combining with the drawings in the examples of the present application. Obviously, the described examples are only part of the examples in the present application, rather than all of them. Based on the examples in the present application, the other examples obtained by those skilled in the art without inventive efforts all fall within the protection scope of the present invention.

In the description of the present application, it should be understood that the terms “first” and “second” are used for descriptive purposes only and cannot be understood as indicating or implying the relative importance or implying the number of the indicated technical features. Thus, features limited with “first” and “second” can explicitly or implicitly include one or more of said features. In the description of the present application, the term “multiple” means two or more, unless otherwise specifically limited.

In the description of the present invention, it should be noted that unless otherwise explicitly defined and limited, terms such as “installing” “linking” and “connecting” should be broadly understood. For example, they can refer to fixed connections or detachable connections, or integral connections; they can be mechanical connections or electrical connections or can communicate with each other; they can be direct connections or indirect connections through an intermediate medium, and can be internal connections between two elements or interactions between two elements. For those ordinarily skilled in the art, they can understand the specific meanings of the above terms in the present application according to specific circumstances.

The following disclosure provides many different embodiments or examples to realize the different structures of the present application. To simplify the disclosure of the present application, specific examples of components and settings are described below. Of course, they are merely illustrative and are not intended to limit the present application. Furthermore, reference numbers and/or reference letters may be repeated in different examples of the present application. Such repetition is for the purpose of simplification and clarity, and does not indicate the relationship between the various embodiments and/or settings under discussion. Additionally, the present application provides examples of various particular processes and materials, but those ordinarily skilled in the art can realize the application of other processes and/or the use of other materials.

It is necessary to elaborate on the background for the creation of the invention of the present application before introducing the technical solutions of the present application.

With the development of the semiconductor industry, the performance, power and other parameters of chips are continuously improved and the sizes of chips also get larger and larger. However, with the miniaturization of electronic devices, there is a certain conflict between the increasing size of chips and the requirement for smaller package size. Therefore, it is necessary to solve the problem of packaging a larger-size chip within a smaller package.

In light of this, the present application provides a packaging structure for large-size chips adapted to small-size packages, which can package larger-size chips under the premise of reducing current package size.

According to FIG. 3, the present application provides a packaging structure for large-size chips adapted to small-size packages, including a frame, a first solder pad cavity 12 and a second solder pad cavity 22 located in the frame, and a chip cavity 41 located above the first solder pad cavity 12, a channel 50 opened on the proximal side of the frame. The first solder pad cavity 12 partly extends above part of the second solder pad cavity 22, and is spaced apart from the second solder pad cavity 22. The first solder pad cavity 12 and the second solder pad cavity 22 are intersected and misaligned. The channel 50 is located on one side of the two solder pad cavities, with the inner wall of the channel 50 being a metallized hole wall 51.

Wherein the first solder pad cavity 12, the second solder pad cavity 22, and the chip cavity 41 are respectively used to place the first solder pad, the second solder pad, and the chip.

Wherein the metallized hole wall 51 is defined as the inner wall of the channel 50, which is made of metallic materials. In other examples of the present application, the inner wall of the channel 50 only needs to have electrical conductivity.

Wherein the proximal side refers to the area close to the outer edge of the packaging structure 100.

As stated above, according to the present application, the intersection and misalignment are defined as two solder pad cavities in non-contact intersection in the horizontal direction and being spaced apart in the vertical direction. More exactly speaking, the first solder pad cavity 12 partly extends above part of the second solder pad cavity 22, and is spaced apart from the second solder pad cavity 22.

As stated above, “large-size” in the large-size chips adapted to small-size packages refers to the size relative to the package in the prior art; the “small-size” refers to the size relative to the chip in the package in the prior art. They are comparisons of sizes for the same object, not comparisons between the size of the package and the size of the chip.

By providing a channel 50 with a metallized hole wall 51 on the proximal side of the packaging structure 100, the packaging structure for large-size chips adapted to small-size packages provided in the present application realizes electrical connection between the solder pad and chip within the package through the channel, replaces the electrical connection wiring manners of multi-layer wiring and via connection, effectively saves internal space within the packaging structure 100, provides more space for the chip inside the packaging structure 100, effectively increases the proportion of the chip within the packaging structure 100 to 60%-70% compared to traditional packaging structures 100, and meets the processing needs for large-size chips adapted to small-size packages.

In an example, the channel 50 can be realized as two channels, each positioned on either side of the first and second solder pads, and both located near the proximal side of the packaging structure 100.

Multiple solder pads and chips are electrically connected through the channel 50 with metallized hole wall 51. The chips are electrically connected to the metallized hole wall 51, and the metallized hole wall 51 is electrically connected to the second solder pad. Compared to the existing complex multi-layer wiring method, the processing technology is simpler, does not require multi-layer wiring, is more efficient and has a lower production cost. The packaging structure for large-size chips adapted to small-size packages provided in the present application realizes the electrical connection between the chips and multiple solder pads through the electrical connection between the metallized hole wall 51 of the channel 50 on the proximal side of the packaging structure 100. The structure is simple and compact, with a rational and effective design.

As stated above, the proportion refers to the ratio of the main surface area of the chip to the cross-sectional area of the packaging structure 100.

In an example, the first solder pad cavity 12 comprises a first pad bottom cavity 121 and a first pad body cavity 122 located above the first pad bottom cavity 121, wherein the first pad body cavity 122 extends above the second solder pad cavity 22.

In an example, the first pad body cavity 122 part extends above the second solder pad cavity 22, and the cross-sectional area of the first pad bottom cavity 121 is smaller than that of the first pad body cavity 122. Compared to the existing chip packaging structure 100, the arrangement of equal cross-sectional areas of the pad bottom cavity and the pad body cavity of the first solder pad cavity 12 saves space occupied by the pad bottom. At the same time, the larger first pad body cavity 122 provides a sufficient mounting surface for soldering and mounting larger chips on the top surface of the first solder pad. The first pad body cavity 122 partly extends above the second solder pad cavity 22, which effectively reduces the overall width of the first solder pad, the second solder pad and the chip, and is conducive to the realization of the miniaturization of the overall structure of the packaging structure 100.

In an example, the cross-sectional area of the first pad body cavity 122 is greater than the cross-sectional area of the first pad bottom cavity 121.

In an example, according to the requirement for the size of the chip in the packaging structure 100, the second solder pad cavity 22 can be configured with the pad bottom cavity and the pad body cavity being equally wide and straight, or it can be arranged with the pad bottom cavity and the pad body cavity being unequal in width with uneven edges. When the second solder pad cavity 22 is arranged with the pad bottom cavity and the pad body cavity being equally wide and edges aligned, it is suitable for the first pad body cavity 122 to extend more above the second solder pad cavity 22 to provide a larger area for chip mounting. When the second solder pad cavity 22 is configured to have the pad bottom cavity and the pad body cavity of unequal width or with uneven edges, the second pad cavity 22 includes a second pad bottom cavity 221 and a second pad body cavity 222 located above the second pad bottom cavity 221. The second pad body cavity 222 is connected to the channel 50, and the first pad body cavity 122 partly extends above the second pad bottom cavity 221. This configuration is suitable for mounting relatively small chips. Meanwhile, the second pad body cavity 222 is interconnected with the metallized hole wall 51 of the channel 50, which is used for the electrical connection between the second solder pad and the metallized hole wall 51.

In an example, the first pad body cavity 122 and the second pad body cavity 222 are laterally spaced apart from each other; and the first pad body cavity 122 and the second pad bottom cavity 221 are longitudinally spaced apart from each other.

In a more concrete example, considering parameters such as the maximum particle size φ of the conventional plastic packaging material EMC filler, and the minimum creepage distance L of the product design, the lateral spacing X≥Min. (φ, L), and the longitudinal spacing Y≥Min. (φ, L).

In an example, an electrical connection wire 42 is provided between the chip cavity 41 and the channel 50, which is used for electrically connecting the chip and the metalized hole wall 51 of the channel 50.

Based on the same inventive concept, the present invention provides a processing method for the above packaging structure for large-size chips adapted to small-size packages, comprising the following steps:
S100, as shown in FIG. 4, preparing a conventional frame, initially injection molding the conventional frame until injection molding materials fill the original plastic packaging cavity, wherein the primary plastic packaging material formed by filling is shown in FIG. 5;
S200, as shown in FIG. 6, thickening the first solder pad initial cavity 11 by electroplating to form the first pad bottom cavity 121;
S300, as shown in FIG. 7, secondary plastic packaging filling to be flush with the top surface of the first pad bottom cavity 121;
S400, as shown in FIGS. 9-12, processing by electroplating to form the first pad body cavity 122 of the first solder pad cavity 12;
S500, as shown in FIGS. 13-14, placing the first solder pad and the second solder pad respectively in the first solder pad cavity 12 and the second solder pad cavity 22, and soldering and mounting the chip on the top surface of the first solder pad, wherein filling plastic packaging material 32 can be seen;
S600, drilling a hole on the same left or right side of the two solder pads (on one side of the two solder pads) and on the proximal edge of the frame to form a channel 50, and metallizing the inner wall of the channel 50 to form a metallized hole wall 51;
S700, electrically connecting the chip to the metalized hole wall 51, and electrically connecting the second solder pad to the metalized hole wall 51;
S800, further filling the frame by injection molding to form a complete packaging structure 100.

In an example, as shown in FIG. 14, based on the different sizes of chips within the packaging structure 100, when the size of the chip to be packaged is relatively small, the second soler pad cavity 22 can be implemented as a setting with unflush top and bottom to provide an electrical connection end of the channel 50 not at the end face of the packaging structure 100. After the step of processing by electroplating to form the first pad body cavity 122 of the first solder pad cavity 12, the following step is further comprised:

As shown in FIG. 8, forming a recess 24 by laser ablation of the second pad body cavity 222 based on the second solder pad initial cavity 21, which combines with electroplating processing to form the second pad body cavity 222 of the second solder pad cavity 22 as shown in FIG. 9.

In an example, in the step of drilling a hole on the same left or right side of the two solder pads (on one side of the two solder pads) and on the proximal edge of the frame to form a channel 50, and metallizing the inner wall of the channel 50 to form a metallized hole wall 51, the inner wall of the channel 50 is subjected to electroless copper plating, sputtering or electroplating to form the metallized hole wall 51.

In an example, in the step of drilling a hole on the same left or right side of the two solder pads (on one side of the two solder pads) and on the proximal edge of the frame to form a channel 50, and metallizing the inner wall of the channel 50 to form a metallized hole wall 51, the channel 50 is shaped by drilling a hole using an ultraviolet laser cutting process with argon gas as the auxiliary gas.

Since multiple chips and multiple pads are obtained from a single PCB board during production and processing, to obtain the packaging structure for large-size chips adapted to small-size packages in the present application, it is necessary to cut and process the entire PCB to obtain multiple packaging structures 100. Therefore, in an example, the processing method provided by the present application also includes a cutting process, which specifically comprises the following step:

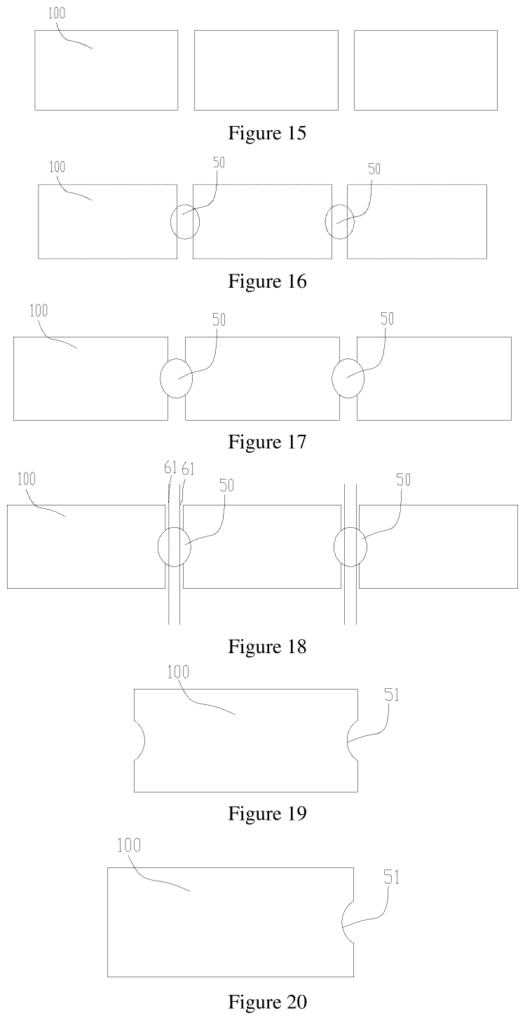

Arranging and cutting the packaging structure 100 on the PCB board as shown in FIG. 15 into multiple packaging structures 100 as shown in FIGS. 19-20.

In an example, as shown in FIGS. 16-17, the shape of the cross-section of the channel 50 is circular.

In an example, as shown in FIG. 18, two cutting lines 61 are provided on the circular cross-section of channel 50, which are symmetrically distributed along the centerline of the circle and are flush with the side edge of the PCB board.

In an example, to avoid hole-copper separation in channel 50 during cutting, a high-power ultraviolet (UV) laser cutting process with argon gas as the auxiliary gas can be used for cutting and processing. High-power ultraviolet laser can achieve precise and fine cutting of thin copper substrates, and has the advantages of narrow kerfs, slight thermal zone impacts, and high-quality kerfs, etc.

The chip and wiring structure inside the single packaging structure 100 are shown in FIGS. 3, 13, and 14. Depending on requirements for the electrical connection in the packaging structure 100, the left end surface of the first solder pad can be implemented as in electrical connection not in contact with the metallized hole wall 51 of the left channel 50, as shown in FIG. 3, or it can be implemented as in electrical connection in contact with the metallized hole wall 51 of the left channel 50, as shown in FIG. 13. The remaining metallized hole wall 51 formed after drilling and separation realizes the electrical connection between the internal wiring of the package and the bottom frame solder pad; when the head structure on the non-chip side of the packaging structure 100 is enlarged, the interconnection wiring on the upper part of the metallized hole wall 51 is connected, and the bottom of the metallized hole wall 51 is only connected to the solder pad on the non-chip side of the packaging frame, not connected to or conducted with the solder pad on the chip side; when the head structure on the chip side of the package is enlarged, the bottom of the metallized hole wall 51 can be connected or not connected to the solder pad on the chip side of the packaging frame, and the position of the metallized hole wall 51 does not exceed the left side edge of the chip in the package.

In an example, the proportion of the chip itself in the package can be further increased by saving the area on the chip side of the package. That is, by using the single-sided drilling interconnection structure of the packaging structure 100, the proportion of the chip itself in the package can be further increased, up to nearly 80 to 90%.

The above examples are merely better embodiments of the present invention, but the protection scope of the present invention is not limited to this. Any change or replacement easily conceived by persons skilled in the art within the technical scope disclosed by the present invention should be covered within the protection scope of the present invention

### INDUSTRIAL APPLICABILITY

By providing a channel with a metallized hole wall on the proximal side of the packaging structure, the packaging structure obtained by a processing method for the above packaging structure for large-size chips adapted to small-size packages, comprising the following steps:
S100, as shown in FIG. 4, preparing a conventional frame, initially injection molding the conventional frame until injection molding materials fill the original plastic packaging cavity, wherein the primary plastic packaging material formed by filling is shown in FIG. 5;
S200, as shown in FIG. 6, thickening the first solder pad initial cavity 11 by electroplating to form the first pad bottom cavity 121;
S300, as shown in FIG. 7, secondary plastic packaging filling to be flush with the top surface of the first pad bottom cavity 121;
S400, as shown in FIGS. 9-12, processing by electroplating to form the first pad body cavity 122 of the first solder pad cavity 12;
S500, as shown in FIGS. 13-14, placing the first solder pad and the second solder pad respectively in the first solder pad cavity 12 and the second solder pad cavity 22, and soldering and mounting the chip on the top surface of the first solder pad, wherein filling plastic packaging material 32 can be seen;
S600, drilling a hole on the same left or right side of the two solder pads (on one side of the two solder pads) and on the proximal edge of the frame to form a channel 50, and metallizing the inner wall of the channel 50 to form a metallized hole wall 51;
S700, electrically connecting the chip to the metalized hole wall 51, and electrically connecting the second solder pad to the metalized hole wall 51;
S800, further filling the frame by injection molding to form a complete packaging structure 100,
   effectively saves internal space within the packaging structure, provides more space for the chip inside the packaging structure, effectively increases the proportion of the chip within the packaging structure to 60%-70% compared to traditional packaging structures, and meets the processing needs for large-size chips adapted to small-size packages; can be applied industrially and can meet the requirements of industrial application.

What is claimed is:

1. A processing method of a packaging structure for large-size chips adapted to small-size packages, characterized in comprising following steps:
initial injection molding a conventional frame until injection molding materials fill original plastic packaging cavity;
thickening a first solder pad initial cavity by electroplating to form a first pad bottom cavity;
secondary plastic packaging filling to be flush with top surface of the first pad bottom cavity;
processing by electroplating to form a first pad body cavity of a first solder pad cavity;
placing a first solder pad and a second solder pad respectively in the first solder pad cavity and second solder pad cavity, and soldering and mounting the chip on top surface of the first solder pad;
drilling a hole on a same left or right side of two solder pads and on a proximal edge of the frame to form a channel, and metallizing an inner wall of the channel to form a metallized hole wall;
electrically connecting the chip to the metalized hole wall, and electrically connecting the second solder pad to the metalized hole wall;
further filling the frame by injection molding to form a complete packaging structure;
wherein the packaging structure for large-size chips adapted to small-size packages includes:
the frame, the first solder pad cavity and the second solder pad cavity located in the frame, and a chip cavity located above the first solder pad cavity, the channel opened on a proximal side of the frame, wherein the first solder pad cavity partly extends above part of the second solder pad cavity and is spaced apart from the second solder pad cavity, and the channel is located on the same left or right side of the two solder pad cavities, with the inner wall of the channel being a metallized hole wall,
wherein, the first solder pad cavity, the second solder pad cavity, and the chip cavity are respectively used to place the first solder pad, the second solder pad, and the chip.

2. The processing method according to claim 1, characterized in that after the step of processing by electroplating to form a first pad body cavity of a first solder pad cavity, the following step is further comprised:
forming a second pad body cavity of the second solder pad cavity by laser ablation combined with electroplating processing based on a second solder pad initial cavity.

3. The processing method according to claim 1, characterized in that in the step of drilling a hole on a same left or right side of two solder pads and on a proximal edge of the frame to form a channel, and metallizing an inner wall of the channel to form a metallized hole wall, the inner wall of the channel is subjected to electroless copper plating to form the metallized hole wall.

4. The processing method according to claim 1, characterized in that in the step of drilling a hole on a same left or right side of two solder pads and on a proximal edge of the frame to form a channel, and metallizing an inner wall of the channel to form a metallized hole wall, the inner wall of the channel is subjected to sputtering to form the metallized hole wall.

5. The processing method according to claim 1, characterized in that in the step of drilling a hole on a same left or right side of two solder pads and on a proximal edge of the frame to form a channel, and metallizing an inner wall of the channel to form a metallized hole wall, the inner wall of the channel is subjected to electroplating to form the metallized hole wall.

6. The processing method according to claim 1, characterized in that in the step of drilling a hole on a same left or right side of two solder pads and on a proximal edge of the frame to form a channel, and metallizing an inner wall of the channel to form a metallized hole wall, the channel is shaped by processing a through-hole using a high-power ultraviolet laser cutting process with argon gas as an auxiliary gas.

7. A packaging structure for large-size chips adapted to small-size packages, characterized in including:
a frame, a first solder pad cavity and a second solder pad cavity located in the frame, and a chip cavity located above the first solder pad cavity, a channel opened on a proximal side of the frame, wherein the first solder pad cavity and the second solder pad cavity are intersected and misaligned, and the channel is located on one side of two solder pad cavities, with inner wall of the channel being a metallized hole wall.

8. The packaging structure for large-size chips adapted to small-size packages according to claim 7, characterized in that the first solder pad cavity, the second solder pad cavity, and the chip cavity are respectively adapted to the first solder pad, the second solder pad, and the chip.

9. The packaging structure for large-size chips adapted to small-size packages according to claim 8, characterized in that the first solder pad cavity comprises a first pad bottom cavity and a first pad body cavity located above the first pad bottom cavity, wherein the first pad body cavity partly extends above the second solder pad cavity.

10. The packaging structure for large-size chips adapted to small-size packages according to claim 9, characterized in that the cross-sectional area of the first pad body cavity is greater than the cross-sectional area of the first pad bottom cavity.

11. The packaging structure for large-size chips adapted to small-size packages according to claim 9, characterized in that the second solder pad cavity comprises a second pad bottom cavity and a second pad body cavity located above the second pad bottom cavity, wherein the second pad body cavity is connected to the channel.

12. The packaging structure for large-size chips adapted to small-size packages according to claim 11, characterized in that the first pad body cavity partly extends above the pad bottom cavity.

13. The packaging structure for large-size chips adapted to small-size packages according to claim 9, characterized in that the first pad body cavity and the second pad body cavity are laterally spaced apart from each other.

14. The packaging structure for large-size chips adapted to small-size packages according to claim 13, characterized in that the first pad body cavity and the second pad bottom cavity are longitudinally spaced apart from each other.

15. The packaging structure for large-size chips adapted to small-size packages according to claim 7, characterized in that an electrical connection wire is provided between the chip cavity and the channel.
